(19) United States
(12) Patent Application Publication
(10) Pub. No.: US 2024/0114804 A1
(43) Pub. Date: Apr. 4, 2024

(54) METHOD FOR PREPARING MULTI-SUPERCONDUCTING MATERIAL LAYERS, QUANTUM DEVICE AND QUANTUM CHIP

(71) Applicant: Alibaba Damo (Hangzhou) Technology Co., Ltd., Hangzhou (CN)

(72) Inventors: Ran GAO, Hangzhou (CN); Chunqing DENG, Hangzhou (CN)

(21) Appl. No.: 18/451,382

(22) Filed: Aug. 17, 2023

(30) Foreign Application Priority Data
Sep. 30, 2022 (CN) 202211215561.4

(51) Int. Cl. H10N 60/01; H10N 60/80

(52) U.S. Cl. CPC H10N 60/0241; H10N 60/80

(57) ABSTRACT

A method for preparing multi-superconducting material layers includes: depositing a first superconducting material layer on a substrate, the first superconducting material layer being formed by covering a first superconducting material in a first target region range with a first hard mask in the first target region range; depositing a second superconducting material on the substrate deposited with the first superconducting material layer; covering the second superconducting material with a second hard mask; and performing etching treatment on the second hard mask and the second superconducting material to obtain a second superconducting material layer formed by covering the second superconducting material in a second target region range with the second hard mask in the second target region range.

### CROSS-REFERENCE TO RELATED APPLICATIONS

The disclosure claims the benefits of priority to Chinese Application No. 202211215561.4, filed on Sep. 30, 2022, which is incorporated herein by reference in its entirety.

### TECHNICAL FIELD

The present disclosure relates to superconducting quantum components, and in particular to a method for preparing multi-superconducting material layers, a quantum device, and a quantum chip.

### BACKGROUND

In related technologies, regional growth is often achieved by using a simple organic photoresist, but the photoresist lacks universal applicability for the reasons of introduction of secondary pollution and very low thermal budget. Alternatively, regional selective growth is performed by using a desolventizing method, but this method likewise lacks the universal applicability due to its relatively high requirements on preparation equipment and very low thermal budget caused by the use of the photoresist.

Therefore, it's difficult to integrate multiple superconducting materials on the same substrate.

### SUMMARY OF THE DISCLOSURE

Embodiments of the present disclosure provide a method for preparing multi-superconducting material layers. The method includes: depositing a first superconducting material layer on a substrate, the first superconducting material layer being formed by covering a first superconducting material in a first target region range with a first hard mask in the first target region range; depositing a second superconducting material on the substrate deposited with the first superconducting material layer; covering the second superconducting material with a second hard mask; and performing etching treatment on the second hard mask and the second superconducting material to obtain a second superconducting material layer formed by covering the second superconducting material in a second target region range with the second hard mask in the second target region range.

Embodiments of the present disclosure provide a quantum device. The quantum device includes a circuit component formed by multiple superconducting materials, and the multiple superconducting materials are obtained by using above method for preparing multi-superconducting material layers.

Embodiments of the present disclosure provide a quantum chip. The quantum chip includes above quantum device.

### BRIEF DESCRIPTION OF THE DRAWINGS

Embodiments and various aspects of the present disclosure are illustrated in the following detailed description and the accompanying figures. Various features shown in the figures are not drawn to scale. Identical reference numerals generally represent identical components in the exemplary implementations of the present disclosure.

FIG. 1 is a flowchart of an exemplary method for preparing multi-superconducting material layers, according to some embodiments of the present disclosure.

FIG. 2 is a flowchart illustrating an exemplary process of integrating titanium nitride of different thicknesses on a substrate, according to some embodiments of the present disclosure.

FIG. 3 is a schematic diagram illustrating an exemplary integration, according to some embodiments of the present disclosure.

FIG. 4 is a schematic diagram illustrating an exemplary wet etching, according to some embodiments of the present disclosure.

FIG. 5 is a schematic diagram illustrating an exemplary photolithography, according to some embodiments of the present disclosure.

FIG. 6 is a schematic diagram illustrating an exemplary material deposition and patterning, according to some embodiments of the present disclosure.

FIG. 7A is a schematic diagram of an optical pattern, according to some embodiments of the present disclosure.

FIG. 7B is an atomic-force microscope scanning image, according to some embodiments of the present disclosure.

FIG. 7C is a schematic diagram of a TiN film surface, according to some embodiments of the present disclosure.

FIG. 7D is a first schematic diagram of X-ray scanning results, according to some embodiments of the present disclosure.

FIG. 7E is a second schematic diagram of X-ray scanning results, according to some embodiments of the present disclosure.

FIG. 8 is a schematic diagram of a quantum computer, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms or definitions incorporated by reference.

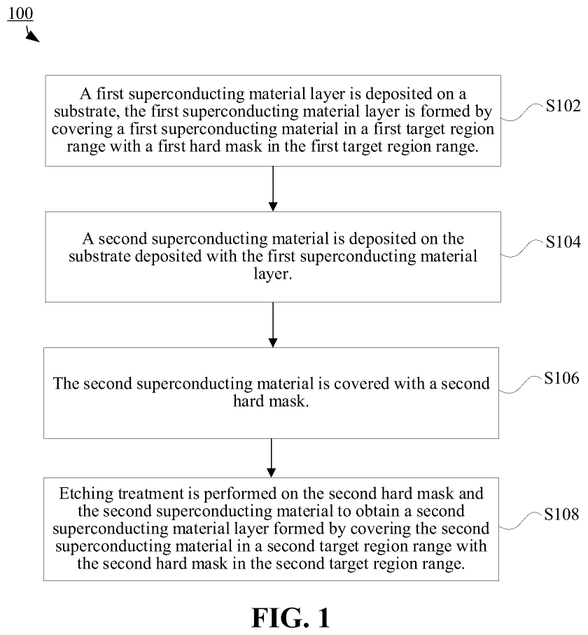

According to some embodiments of the present disclosure, a method for preparing multi-superconducting material layers is provided. FIG. 1 is a flowchart of an exemplary method 100 for preparing multi-superconducting material layers, according to some embodiments of the present disclosure. As shown in FIG. 1, method 100 includes steps S102 to S108.

At step S102, a first superconducting material layer is deposited on a substrate. The first superconducting material layer is formed by covering a first superconducting material in a first target region range with a first hard mask in the first target region range.

At step S104, a second superconducting material is deposited on the substrate deposited with the first superconducting material layer.

At step S106, the second superconducting material is covered with a second hard mask.

At step S108, etching treatment is performed on the second hard mask and the second superconducting material to obtain a second superconducting material layer formed by covering the second superconducting material in a second target region range with the second hard mask in the second target region range.

Etching is an important step in a semiconductor manufacturing process, a manufacturing process of a microelectronic integrated circuit (IC) chip and a micro/nano manufacturing process, and is a main process for graphical processing, which is associated with photolithography. In fact, the so-called etching is photolithography and corrosion in a narrow sense, in which a photoresist is first regionally subjected to light exposure and the exposed portions to be removed by corrosion treatment in specific manners. The etching is a process for selectively removing undesired materials from the surface of a wafer under process by using a chemical or physical method, with the objective to correctly copy a mask pattern onto the wafer under process. With the development of a micro-manufacturing process, the etching is broadly defined as a general term of stripping and removing materials through solutions, reactive ions or other mechanical means, and has become a ubiquitous term for micro-manufacturing. The simplest and most commonly used classes of etching include: dry etching and wet etching. Apparently, the difference between them lies in that the wet etching uses a solvent or solution to perform etching. The wet etching is a pure chemical reaction process, and refers to a process for removing portions not masked by a masking film material by using a chemical reaction between the solution and a pre-etched material so as to achieve the aim of etching. The wet etching has the advantages of good selectivity, good reproducibility, high production efficiency, simple equipment, and low cost. There are many types of dry etching, including photo-volatilization, vapor-phase corrosion, plasma corrosion, etc. The dry etching is mainly divided into the following three types according to types of materials to be etched: metal etching, dielectric etching, and silicon etching. The dielectric etching is used for etching dielectric materials, such as silicon dioxide. The dry etching has the following advantages: good anisotropy, high selection ratio, good controllability, flexibility and repeatability, safety in fine line operation, easiness for realizing automation, no chemical waste liquid, no pollution introduced in a treatment process, and high cleanliness.

With above steps, the superconducting materials are deposited on the substrate in sequence according to their types needing to be integrated, and one layer of hard mask covers thereon each time the superconducting material is deposited; and after the target region range of the superconducting material deposited on the substrate each time is determined, a technical effect of realizing regional integration of multiple superconducting materials on the same substrate is implemented skillfully in an etching manner, thereby solving the technical problem of difficulty of integrating the multiple superconducting materials on the same substrate.

In some embodiments, the step S102 for depositing the first superconducting material layer, which is formed by covering the first superconducting material in the first target region range with the first hard mask in the first target region range, on the substrate includes: depositing the first superconducting material on the substrate; covering the first superconducting material with the first hard mask; determining the first target region range in which the first superconducting material is to retain on the substrate; and gradually etching away a first hard mask of a first other region range in the first hard mask, and a superconducting material of the first other region range in the first superconducting material, respectively, so as to obtain the first superconducting material layer formed by covering the first superconducting material in the first target region range with the first hard mask in the first target region range, where the first other region range is a region range on the substrate in addition to the first target region range.

After the first hard mask covers the first superconducting material deposited on the substrate, various methods may be used for etching away the first hard mask of the first other region range on the substrate in addition to the first target region range in the first hard mask. For example, the first hard mask of the first other region range in the first hard mask may be etched away in a manner combining photolithography and dry etching. Various methods may also be used when the superconducting material of the first other region range on the substrate in addition to the first target region range in the first superconducting material is etched away so that the finally obtained first superconducting material layer is a combination of covering the first superconducting material of the first target region range with the first hard mask in the first target region range on the substrate. For example, the superconducting material of the first other region range in the first superconducting material may be etched way in a wet etching manner.

The process of depositing the second superconducting material layer is similar to the process of depositing the first superconducting material layer, and the processes both include the steps of firstly, depositing one layer of superconducting material on a substrate and depositing one layer of hard mask on the superconducting material; then, etching away the hard mask and the superconducting material of the other region range in addition to a target region by using a method combining photolithography and dry etching and further combing with wet etching, so as to obtain a superconducting material layer formed by covering the superconducting material in the target region range with the hard mask. The difference between the process of depositing the second superconducting material layer and the process of depositing the first superconducting material layer is that: the superconducting materials used in the two processes of deposition are different so as to achieve the aim of integrating different superconducting materials on the same substrate. During the process, when the hard mask is removed by using photolithography and dry etching, the hard mask is firstly patterned by photolithography, that is, a graphic region where the hard mask needs to be removed is determined, and then the hard mask to be removed is etched away by dry etching based on the determined graphic region.

In some embodiments, the step S108 that performing etching treatment on the second hard mask and the second superconducting material to obtain the second superconducting material layer formed by covering the second superconducting material in the second target region range with the second hard mask in the second target region range includes: gradually etching away the second hard mask of the second other region range in the second hard mask, and etching away a superconducting material of the second other region range in the second superconducting material, respectively, so as to obtain the second superconducting material layer, where the second other region range is a region range on the substrate in addition to the second target region range, and the second superconducting material layer is formed by covering the second superconducting material in the second target region range with the second hard mask in the second target region range.

During the process, various methods may also be used for etching away the second hard mask of the second other region range in the second hard mask. For example, the second hard mask of the second other region range in the second hard mask is etched away in a manner combining photolithography and dry etching. Various method may also be used for etching away the superconducting material of the second other region range in the second superconducting material. For example, the superconducting material of the second other region in the second superconducting material is etched way in a wet etching manner.

It should be noted that the above deposition of the first superconducting material layer and the second superconducting material layer on the substrate is merely an example. According to specific deposition requirements or when the substrate is used for subsequent fabrication of different superconducting devices, more types of superconducting material layers may further be deposited on the substrate, which will not be described here.

In some embodiments, after the step S108 that performing etching treatment on the second hard mask and the second superconducting material to obtain a second superconducting material layer formed by covering the second superconducting material in a second target region range with the second hard mask in the second target region range, method 100 further includes: etching away the first hard mask on the first superconducting material layer and the second hard mask on the second superconducting material layer to obtain a first target superconducting device on the substrate. After the first superconducting material and the second superconducting material are simultaneously integrated on one substrate, a desired superconducting device is prepared based on a process for preparing the superconducting device and preparation steps, and a superconducting circuit, a superconducting chip, a quantum chip, and a quantum computer may be prepared in the future based on the prepared superconducting device.

In some embodiments, during the etching away the first hard mask on the first superconducting material layer and the second hard mask on the second superconducting material layer to obtain the first target superconducting device on the substrate, a dilute hydrofluoric acid (DHF) solution may be used for etching away the first hard mask on the first superconducting material layer and the second hard mask on the second superconducting material layer to obtain the first target superconducting device on the substrate.

After two different types of superconducting materials have been integrated on the substrate, that is, the first superconducting material layer and the second superconducting material layer have been deposited on the substrate, if only the first superconducting material and the second superconducting material need to be integrated on the substrate, uniform treatment may be carried out on the hard masks covering on the superconducting materials according to actual application requirements after the first superconducting material layer and the second superconducting material layer are obtained by depositing. For example, the first hard mask on the first superconducting material layer and the second hard mask on the second superconducting material layer may be etched away with the DHF solution by utilizing a wet etching method, where the DHF solution is only capable of dissolving the hard masks, but not dissolving the superconducting materials or its speed of dissolving the superconducting materials is very slow, so as to achieve the effect of only removing the hard masks. The wet etching method is used, that is, the hard masks on the first superconducting material layer and the second superconducting material layer are etched away by using a solution etching agent. Compared with a manner of etching with the photoresist, the solution etching agent can immerse into all edges of the hard masks, which are in contact with the superconducting materials, and therefore, the hard masks at edge gaps of the superconducting materials can be more completely removed, so that the first superconducting material and the second superconducting material integrated on the substrate are more pure, laying a foundation for subsequent preparation of precise superconducting devices.

In some embodiments, after step S108 that performing etching treatment on the second hard mask and the second superconducting material to obtain a second superconducting material layer formed by covering the second superconducting material in a second target region range with the second hard mask in the second target region range, to meet the requirements on the subsequent preparation of devices, other superconducting material layers may also be continually integrated on the substrate. For example, a third superconducting material can also be deposited on the first superconducting material layer and a first other region range, where the first other region range is a region range on the substrate in addition to the first target region range. The third superconducting material is covered with a nitride used as a third hard mask. A third target region range is determined in which the third superconducting material is to retain on the substrate. Etching treatment on the third hard mask and the third superconducting material is performed to obtain a third superconducting material layer formed by covering the third superconducting material in the third target region range with the third hard mask in the third target region range. The third superconducting material layer is obtained on the substrate by using the above similar treatment method of integrating the second superconducting material layer, that is, the third superconducting material is integrated on the substrate.

In some embodiments, the performing etching treatment on the third hard mask and the third superconducting material to obtain a third superconducting material layer formed by covering the third superconducting material in the third target region range with the third hard mask in the third target region range includes: gradually etching away a third hard mask of a third other region range in the third hard mask, and etching away a superconducting material of the third other region range in the third superconducting material, respectively, so as to obtain the third superconducting material layer formed by covering the third superconducting material in the third target region range with the third hard mask in the third target region range, where the third other region range is a region range on the substrate in addition to the third target region range. On the basis of the above similar treatment method of obtaining the second superconducting material layer, the third hard mask of the third other region range in the third hard mask is etched away in a manner combining photolithography and dry etching. The manner combining photolithography and dry etching has the advantages of mature technology and high efficiency, and therefore, the third superconducting material layer can be obtained efficiently. In addition, the superconducting material of the third other region range in the third superconducting material is etched away in a wet etching manner, and the etching agent selected by the used wet etching method can be well dissolved in the superconducting material, but is insoluble to the hard mask, so that the superconducting material in the third other region is etched more thoroughly and the precision of the third superconducting material layer is effectively guaranteed.

In some embodiments, after the performing etching treatment on the third hard mask and the third superconducting material to obtain a third superconducting material layer formed by covering the third superconducting material in the third target region range with the third hard mask in the third target region range, the method further includes: etching away the first hard mask on the first superconducting material layer, the second hard mask on the second superconducting material layer, and the third hard mask on the third superconducting material layer to obtain a second target superconducting device on the substrate.

After two different types of superconducting materials have been integrated on the substrate, that is, the first superconducting material layer and the second superconducting material layer have been deposited on the substrate, if the third superconducting material still needs to be integrated on the substrate, the third superconducting material layer can be obtained by depositing again in a manner similar to the deposition of the first superconducting material layer and the second superconducting material layer according to actual application requirements after the first superconducting material layer and the second superconducting material layer are obtained by depositing. After the deposition is finished, the hard mask is removed along with those of the first superconducting material layer and the second superconducting material layer.

The above method for etching away the mask may be the manner combining photolithography and dry etching, and the method for etching away the superconducting material may be the wet etching manner. For example, the first hard mask of the first other region range in the first hard mask, the second hard mask of the second other region range in the second hard mask, and the third hard mask of the third other region range in the third hard mask may be etched away, respectively, in the manner combining photolithography and dry etching. The superconducting material of the first other region range in the first superconducting material, the superconducting material of the second other region range in the second superconducting material, and the superconducting material of the third other region range in the third superconducting material may be etched away, respectively, in the wet etching manner.

It should be noted that the method of the embodiments of the present disclosure is not limited to the integration of two or three types of superconducting materials, and the regional integration of multiple superconducting materials on the substrate may be implemented through the above integration method according to the actual application requirements.

It should be noted that when there is a need of integrating different superconducting materials on the same horizontal plane of the substrate, the method in the above embodiments may be used. If there is a need of integrating different superconducting materials on a vertical plane, after a superconducting material at the bottom is integrated, a hard mask covering on the superconducting material is etched firstly to expose the superconducting material that should be at the bottom and then deposit one layer of superconducting material that should be at the top on the exposed superconducting material.

In some embodiments, the hard masks used in the above process for obtaining three types of superconducting material layers, that is, the first hard mask, the second hard mask, and the third hard mask, may be masks made of the same material, and may alternatively be masks made of different materials having similar properties. For example, all of the first hard mask, the second hard mask, and the third hard mask may be nitrides. The nitrides may be silicon nitride, etc.

It should be noted that the material of the above third hard mask may be the same as those of the first hard mask and the second hard mask, that is, a nitride (for example, silicon nitride). When the material of the third hard mask is the same as those of the first hard mask and the second hard mask, the hard masks are also easy to remove uniformly by using an etching solution (for example, the DHF solution) after all superconducting materials are integrated.

In some embodiments, the wet etching manner may be used for etching the superconducting materials: a method for etching by using a predetermined etching agent. There may be various types of predetermined etching agents for selection, as long as corresponding superconducting materials can be completely etched away without affecting masks needing to be protected correspondingly. For example, the above predetermined etching agent may be an SC-1 solution. A standard clean agent for silicon wafers (SC for short) is widely applied to silicon wafer cleaning in the industries of photovoltaics, electronics, etc. Since the silicon wafer may be polluted during transportation and the surface cleanliness is not very high, which will have a great impact on the upcoming corrosion and etching, it is necessary to carry out a series of cleaning operations on the surface of the silicon wafer firstly. A general idea of cleaning is to: firstly, remove organic contaminants on the surface, and then dissolve an oxide film for the reason that an oxide layer is a “contaminant trap” which will cause epitaxy defects; and secondly, remove particles, metal, etc., and passivate the surface of the silicon wafer at the same time. The SC-1 cleaning agent is an alkaline solution capable of removing particles and organic matters. A SC-2 cleaning agent is used for removing residual organics and metallic particles on the surface of the silicon wafer.

In this example of the present disclosure, the selection of the used solution for wet etching focuses on the need of a solution capable of only etching away the superconducting materials without affecting the hard masks, and a solution capable of only etching away the hard masks without affecting the superconducting materials. On one hand, this selection may be determined by whether the solution can dissolve the corresponding material alone, and on the other hand, this selection may alternatively be determined by the difference of dissolution rates of the solution for different materials. For example, the superconducting materials (which may be nitrogen-based superconducting materials, for example, titanium nitride) are dissolved by using the SC-1 solution, and the hard masks (for example, silicon nitride) are dissolved by using the DHF solution. Silicon nitride is dissolved in the SC-1 solution extremely slowly, but the nitrogen-based superconducting materials can be dissolved therein more rapidly; while the nitrogen-based superconducting materials can exist in the DHF solution stably, silicon nitride can be dissolved in the DHF solution. Therefore, the effect of etching away the superconducting materials or the hard masks alone may be achieved, respectively, by using the dissolution conditions of the superconducting materials and the hard masks in the two solutions.

The superconducting materials are deposited on the substrate in sequence through the above steps according to their types needing to be integrated, and one layer of hard mask covers thereon each time the superconducting material is deposited. After the target region range and the other region range are determined, the regional integration of the superconducting materials on the substrate may be implemented by using the hard masks. For example, when the superconducting material in the first target region range needs to be retained, the first hard mask in the first other region range in the first hard mask is etched away in a manner combining photolithography and dry etching, that is, only the first hard mask in the first target region range is retained. Then, the first superconducting material exposed in the first other region range is etched away by using a wet etching manner (i.e., using an etching agent capable of only dissolving the superconducting materials but not dissolving the hard masks), that is, only the first superconducting material in the first target region range is retained. If there is a need of integrating other types of superconducting materials in other regions, deposition and etching may be carried out by using the same manner, and an etching agent capable of only dissolving the hard masks but not dissolving the superconducting materials may be uniformly used for etching the hard masks after the regional integration of all required superconducting materials is completed, so as to remove the hard masks and only retain the superconducting materials integrated on the substrate, thereby realizing the technical effect of realizing the regional integration of multiple superconducting materials on the same substrate, and further solving the technical problem of difficulty of integrating the multiple superconducting materials on the same substrate.

Based on the above embodiments, the present disclosure provides an optional embodiment described below.

Some embodiments of the present disclosure provide a method for preparing an epitaxial nitride-based superconducting material integrated circuit component. The key of such method is that it enables materials with different thicknesses, chemical compositions, and process conditions to be subjected to regional selective integration on the same wafer (i.e., the above-mentioned substrate). A wafer refers to a silicon wafer used in the fabrication of silicon semiconductor circuits and its starting material is silicon. After being dissolved, high-purity polysilicon is doped with a silicon crystal seed, and then is slowly pulled to form cylindrical monocrystalline silicon. A silicon crystal rod is ground, polished, and cut into slices to form silicon crystal wafers, that is, wafers.

A silicon nitride layer, acting as a hard mask or a separation layer, is used for regional selective epitaxial growth of functional films, and the SC-1 solution is used for etching the functional films (i.e., all the above superconducting materials). Such method may lay a foundation for the construction of more complicated quantum circuit structures. Epitaxial growth refers to the growth of a single-crystal layer with certain requirements and a crystal orientation identical to a substrate on a single-crystal substrate (substrate), as if an original crystal has been extended outward for a certain length. The purpose of developing an epitaxial growth technology is to manufacture high-frequency and high-power devices, in which the collector series resistance needs to be reduced and materials are also required to be able to withstand high voltage and high current. Therefore, it is necessary to grow a thin high-resistance epitaxial layer on a low-resistance substrate. An epitaxially grown new single-crystal layer may be different from the substrate in terms of conduction type, resistivity, etc., and may also grow a plurality of layers of single crystals with different thicknesses and different requirements, thereby greatly improving the flexibility of device design and the performance of devices. An epitaxy process is also widely applied to a PN junction isolation technology in integrated circuits and the improvement of material quality in large-scale integrated circuits.

It is often required to integrate materials with different thicknesses, different chemical compositions, and different deposition conditions on the same substrate plane during the manufacturing of superconducting quantum circuits. The integration needs to be completed in such a way that the expected performance of each material is not influenced in a process flow. In addition, with respect to specific applications in which high-quality growth materials are needed, it is desired that such integration can realize the epitaxial growth of various materials with large thermal budget. This means that the process should not influence a growth surface of a subsequent material after the etching of each layer. In other words, one key technology implementation is to minimize the influences on wafer surfaces by an etching process, without the need of obtaining one wafer surface structure suitable for epitaxial growth by additional surface reconstruction processing. Thermal budget is the explicit processing temperature and the processing time required by a specific manufacturing process. One of targets of a semiconductor process is to reduce the thermal energy required by silicon as much as possible. One factor that determines process conditions for almost silicon-based semiconductors is to minimize the thermal budget by cooling or shortening time.

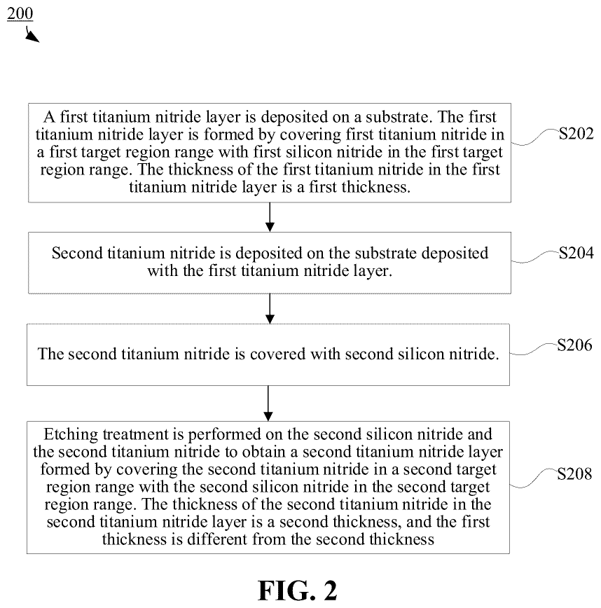

Based on the above considerations, embodiments of the present invention provide a process for integrating titanium nitride of different thicknesses on a substrate. FIG. 2 is a flowchart illustrating an exemplary process 200 of integrating titanium nitride of different thicknesses on a substrate, according to some embodiments of the present disclosure. As shown in FIG. 2, process 200 includes steps S202 to S208.

At step S202, a first titanium nitride layer is deposited on a substrate. The first titanium nitride layer is formed by covering first titanium nitride in a first target region range with first silicon nitride in the first target region range. The thickness of the first titanium nitride in the first titanium nitride layer is a first thickness.

At step S204, second titanium nitride is deposited on the substrate deposited with the first titanium nitride layer.

At step S206, the second titanium nitride is covered with second silicon nitride.

At step S208, etching treatment is performed on the second silicon nitride and the second titanium nitride to obtain a second titanium nitride layer formed by covering the second titanium nitride in a second target region range with the second silicon nitride in the second target region range. The thickness of the second titanium nitride in the second titanium nitride layer is a second thickness, and the first thickness is different from the second thickness.

During the above process for depositing titanium nitride of different thicknesses on the substrate, the first titanium nitride is covered with the first silicon nitride during the preparation of the second titanium nitride, so the first titanium nitride is not affected by the preparation of the second titanium nitride layer, that is, the first titanium nitride deposited on the substrate is effectively protected. Moreover, the above first target region range is different from the above second target region range, that is, a whole process of preparing titanium nitride of different thicknesses in different region ranges of the same substrate is not only efficient in operation, but can also effectively ensure the purity of all titanium nitride of different thicknesses, thereby improving the precision of subsequent preparation of quantum devices.

As described above, this implementation provides a technology to implement regional deposition and integration of nitrogen-based superconducting materials, and illustrates its feasibility by taking the integration of titanium nitride (TiN) of different thicknesses as an example. In short, silicon nitride (SiNx) is selected as a hard mask material and the SC-1 solution (i.e., a mixture of ammonia, hydrogen peroxide and water at a composition ratio of 1:1:6) is selected as the etching agent. The reasons for such selection include: firstly, silicon nitride is stable below 1000° C., which provides greater thermal budget for all deposition steps. Secondly, silicon nitride has an extremely slow etching speed (<1 nm/min) in the SC-1 solution, so it may be used as an ideal mask layer or separation layer for different functional materials (i.e., superconducting materials with different thicknesses or properties). Finally, nitride-based superconducting materials are stable in DHF solution, but the silicon nitride layer may be dissolved in the DHF solution. Therefore, the silicon nitride layer may be very easily removed from the DHF solution. Since the etching selectivity of silicon nitride and the nitride-based superconducting materials in the SC-1 solution and the DHF solution approaches infinity, such combination may be repeated indefinitely, and various superconducting materials can be selectively integrated on the same substrate plane.

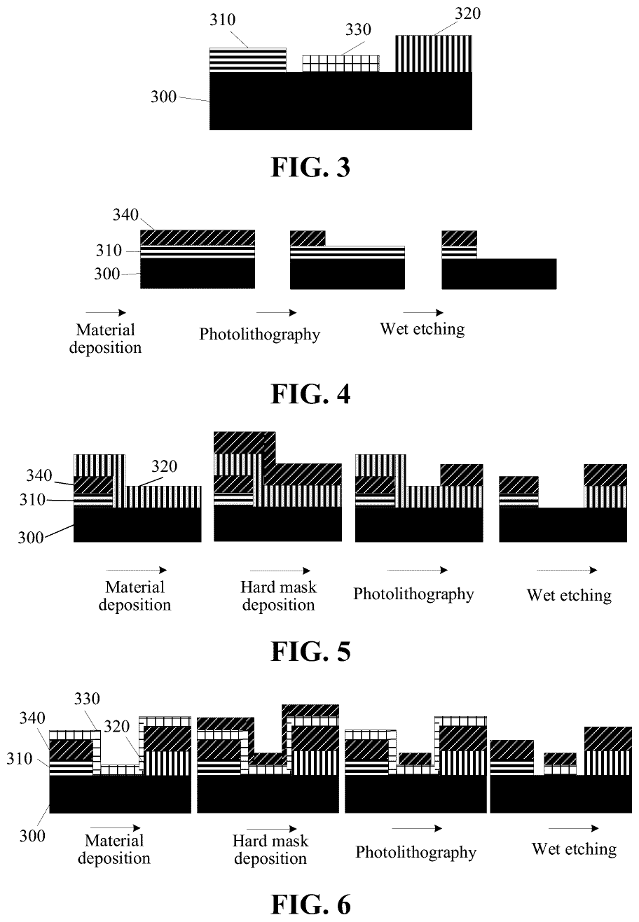

In some embodiments of the present disclosure, a process flow for integrating three different types of materials on the same substrate (for example, a sapphire substrate) to realize a desired geometrical shape is described. FIG. 3 to FIG. 6 illustrate processes for an exemplary integration, according to some embodiments of the present disclosure. FIG. 3 is a schematic diagram illustrating an exemplary integration, according to some embodiments of the present disclosure. As shown in FIG. 3, a first superconducting material layer 310, a second superconducting material layer 320, and a third superconducting material layer 330 are integrated on the same substrate 300. This process starts from the deposition in which a first layer is labeled as a sheet material 310 (the first superconducting material). Then, the sheet material 310 is covered with a silicon nitride layer used as a hard mask layer. Before the etching of the sheet material 310, a pattern is firstly generated in the hard mask layer through a photolithography and dry etching method, and a region needing to be etched away in the sheet material 310 is exposed.

FIG. 4 is a schematic diagram illustrating an exemplary wet etching, according to some embodiments of the present disclosure. The SC-1 solution is used for wetly etching the sheet material 310, and the silicon nitride mask layer 340 is retained on the sheet material 310 after wet etching, so as to complete the integration of a first superconducting layer. After the completion of the first layer, a second layer of superconducting material (sheet material 320) needing to be integrated is deposited on a wafer which has been patterned and contains the sheet material 310 and a hard template.

FIG. 5 is a schematic diagram illustrating an exemplary photolithography, according to some embodiments of the present disclosure. After a second superconducting layer (sheet material 320) is deposited, another layer of silicon nitride mask is coated on the sheet material 320. Photolitho-patterning, dry etching, and wet etching as shown in FIG. 5 are carried out to realize patterning operation on the sheet material 320. It is worth noting that the etching may be carried out on any region of the wafer, and therefore, it is regional selective deposition for each superconducting layer in nature. Another important factor is that since the first layer (i.e., sheet material 310) is protected by the remaining silicon nitride mask layer 340, the impact of the second wet etching on this layer can be ignored.

FIG. 6 is a schematic diagram illustrating an exemplary material deposition and patterning, according to some embodiments of the present disclosure. The deposition and patterning on a third nitrogen-based superconducting material (sheet material 330) are realized according to a flow as shown in FIG. 6. With respect to a final layer (sheet material 330), all steps are consistent to those of the above process.

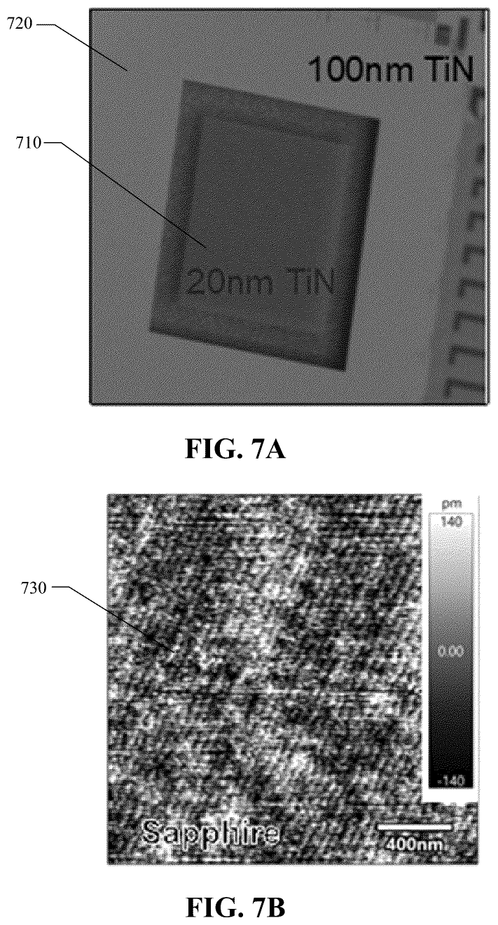

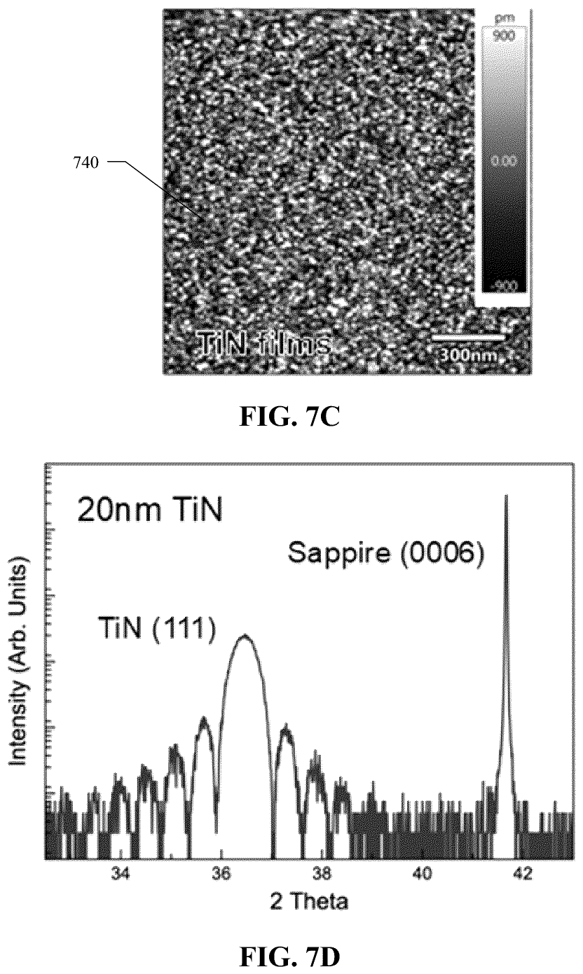

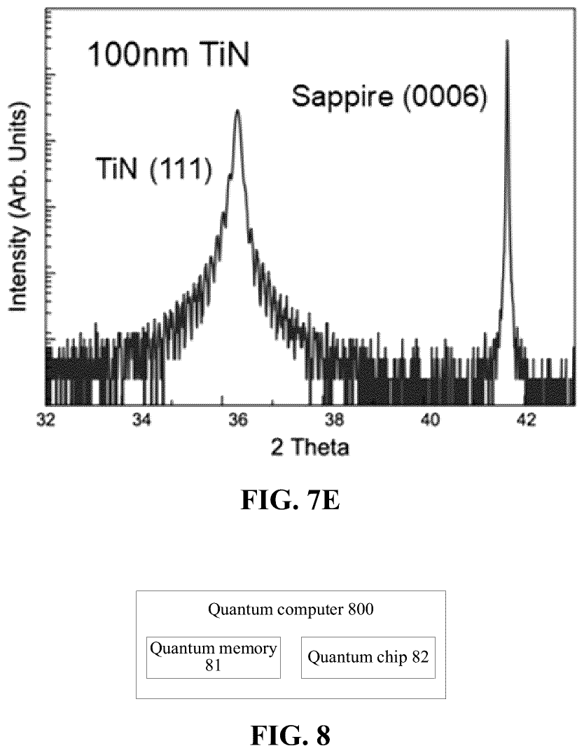

In some embodiments of the present invention, the integration of epitaxial TiN of different thicknesses on the same sapphire substrate has been researched to verify the feasibility of such inventive method. FIG. 7A is a schematic diagram of an optical pattern, according to some embodiments of the present disclosure. It can be seen from FIG. 7A that a test pattern of a TiN film 710 with the thickness of 20 nm is located at the center of an opening region and is surrounded by a TiN layer 720 with the thickness of 100 nm. After two times of film deposition and etching, a sapphire surface subjected to the wet etching is inspected first. FIG. 7B illustrates an atomic-force microscope scanning image, according to some embodiments of the present disclosure. As shown in FIG. 7B, the sapphire surface 730 keeps high quality and clearly visible atomic steps can be observed. This indicates that the deposition and etching of a functional film will have no impact on the surface quality of wafers. Therefore, such etching process may be repeated multiple times in principle to realize regional deposition of high-quality nitrogen-based superconducting films of different types (such as thickness, chemical ratio and process conditions). FIG. 7C illustrates a schematic diagram of a TiN film 740 surface, according to some embodiments of the present disclosure. With respect to TiN film 740, a TiN surface is also very smooth and has root mean square surface roughness of about 340 pm. To further inspect the quality of TiN film 740, an X-ray diffraction method is used for inspecting the crystallization quality of TiN film 740 in different thickness regions. FIG. 7D illustrates a first schematic diagram of X-ray scanning results, according to some embodiments of the present disclosure, and FIG. 7E illustrates a second schematic diagram of X-ray scanning results, according to some embodiments of the present disclosure. As shown in FIG. 7D and FIG. 7E, both sharp diffraction peaks and Laue diffraction fringes of TiN under (111) diffraction conditions indicate that high-crystallinity epitaxial growth of the TiN films of different thicknesses deposited in different regions is realized. Through researches of AFM (Atomic Force Microscope) and X-ray, one conclusion may be drawn properly: this integration technology may be effectively applied to applications in which films of different types (such as thickness, chemical ratio and process conditions) need to be deposited on the same wafer plane. More importantly, this technology will not reduce the crystallinity, surface roughness and surface cleanliness of materials.

It should be noted that for each of the foregoing method embodiments, for ease of description, the method embodiment is described as a series of action combinations, but a person skilled in the art should know that the present disclosure is not limited to an order of described actions, because according to the present disclosure, some steps may be performed in another order or at the same time. In addition, a person skilled in the art should also know that all the embodiments described in this specification are exemplary embodiments, and the related actions and modules are not necessarily required in the present disclosure.

According to some embodiments of the present disclosure, a quantum device is further provided. The quantum device includes a circuit component formed by multiple superconducting materials, and the multiple superconducting materials are obtained by using the method for preparing multi-superconducting material layers described above.

According to some embodiments of the present disclosure, the quantum device is a Fluxonium quantum bit.

According to some embodiments of the present disclosure, a superconducting circuit is further provided. The superconducting circuit includes the above quantum device.

According to some embodiments of the present disclosure, a quantum chip is further provided. The quantum chip includes the above quantum device.

According to some embodiments of the present disclosure, a quantum computer is further provided. FIG. 8 is a schematic diagram of a quantum computer, according to some embodiments of the present disclosure. The quantum computer may be any quantum computer device in a quantum computer group. As shown in FIG. 8, a quantum computer 800 includes: a quantum memory 81 and a quantum chip 82 as described above.

A person of ordinary skill in the art may understand that the structure shown in FIG. 8 is merely an illustration, and FIG. 8 does not define the structure of the above electronic device. For example, quantum computer 800 may alternatively include more or fewer components than those shown in FIG. 8, or has a configuration different from that shown in FIG. 8.

A person of ordinary skill in the art may understand that all or some of the steps of various methods of the foregoing embodiments may be implemented by a program instructing relevant hardware. The program may be stored in a computer-readable storage medium. The storage medium may include: a flash drive, a read-only memory (ROM), a random access memory (RAM), a magnetic disk, an optical disc, and the like.

In the several embodiments provided in the present disclosure, it should be understood that the disclosed technical content may be implemented in other manners. The embodiments described above are merely exemplary. The whole implementation process of the above embodiments also needs to be combined with control program units of a computer, and the division of the units is merely the division of logic functions, and may use other division manners during actual implementation. For example, a plurality of units or components may be combined, or may be integrated into another system, or some features may be omitted or not performed. In addition, the coupling, or direct coupling, or communication connection between the displayed or discussed components may be the indirect coupling or communication connection through some interfaces, units, or modules, and may be electrical or of other forms.

The units described as separate components may or may not be physically separated, and the components displayed as units may or may not be physical units, and may be located in one place or may be distributed over a plurality of network units. Some or all of the units may be selected according to actual needs to achieve the objectives of the solutions of the embodiments.

In addition, all functional units in the embodiments of the present invention may be integrated into one processing unit, or each of the units may be physically separated, or two or more units may be integrated into one unit. The integrated unit may be implemented in the form of hardware, or may be implemented in a form of a software functional unit.

When the integrated unit is implemented in the form of a software functional unit and sold or used as an independent product, the integrated unit may be stored in the computer-readable storage medium. Based on such an understanding, the technical solutions of the present invention essentially, or the part contributing to the prior art, or all or some of the technical solutions may be presented in the form of a software product. The computer software product is stored in the storage medium, and includes several instructions for instructing one computer device (which may be a personal computer, a server, a network device, and the like) to perform all or some of the steps of the methods described in the embodiments of the present invention. The foregoing storage medium includes: various media capable of storing program code such as a USB disk, a ROM, a RAM, a mobile hard disk, a magnetic disk, or an optical disc

The embodiments may further be described using the following clauses:
1. A method for preparing multi-superconducting material layers, comprising:
depositing a first superconducting material layer on a substrate, the first superconducting material layer being formed by covering a first superconducting material in a first target region range with a first hard mask in the first target region range;
depositing a second superconducting material on the substrate deposited with the first superconducting material layer;
covering the second superconducting material with a second hard mask; and
performing etching treatment on the second hard mask and the second superconducting material to obtain a second superconducting material layer formed by covering the second superconducting material in a second target region range with the second hard mask in the second target region range.
2. The method according to clause 1, wherein the depositing the first superconducting material layer on the substrate comprises:
depositing the first superconducting material on the substrate;
covering the first superconducting material with the first hard mask;
determining the first target region range in which the first superconducting material is to retain on the substrate; and
etching away a first hard mask of a first other region range in the first hard mask, and a superconducting material of the first other region range in the first superconducting material, respectively, wherein the first other region range is a region range on the substrate in addition to the first target region range.
3. The method according to clause 1, wherein the performing etching treatment on the second hard mask and the second superconducting material to obtain a second superconducting material layer formed by covering the second superconducting material in a second target region range with the second hard mask in the second target region range comprises:
etching away a second hard mask of a second other region range in the second hard mask, and a superconducting material of the second other region range in the second superconducting material, respectively, wherein the second other region range is a region range on the substrate in addition to the second target region range.
4. The method according to clause 1, wherein after the performing etching treatment on the second hard mask and the second superconducting material to obtain a second superconducting material layer formed by covering the second superconducting material in a second target region range with the second hard mask in the second target region range, the method further comprises:
etching away the first hard mask on the first superconducting material layer and the second hard mask on the second superconducting material layer to obtain a first target superconducting device on the substrate.
5. The method according to clause 4, wherein the etching away the first hard mask on the first superconducting material layer and the second hard mask on the second superconducting material layer to obtain a first target superconducting device on the substrate comprises:
etching away the first hard mask on the first superconducting material layer and the second hard mask on the second superconducting material layer by using a dilute hydrofluoric acid (DHF) solution to obtain the first target superconducting device on the substrate.
6. The method according to clause 1, wherein after the performing etching treatment on the second hard mask and the second superconducting material to obtain a second superconducting material layer formed by covering the second superconducting material in a second target region range with the second hard mask in the second target region range, the method further comprises:
depositing a third superconducting material on the first superconducting material layer and a first other region range, wherein the first other region range is a region range on the substrate in addition to the first target region range;
covering the third superconducting material with a nitride used as a third hard mask;
determining a third target region range in which the third superconducting material is to retain on the substrate; and
performing etching treatment on the third hard mask and the third superconducting material to obtain a third superconducting material layer formed by covering the third superconducting material in the third target region range with the third hard mask in the third target region range.
7. The method according to clause 6, wherein the performing etching treatment on the third hard mask and the third superconducting material to obtain a third superconducting material layer formed by covering the third superconducting material in the third target region range with the third hard mask in the third target region range comprises:
etching away a third hard mask of a third other region range in the third hard mask, and a superconducting material of the third other region range in the third superconducting material, respectively, wherein the third other region range is a region range on the substrate in addition to the third target region range.
8. The method according to clause 6, wherein after the performing etching treatment on the third hard mask and the third superconducting material to obtain a third superconducting material layer formed by covering the third superconducting material in the third target region range with the third hard mask in the third target region range, the method further comprises:
etching away the first hard mask on the first superconducting material layer, the second hard mask on the second superconducting material layer, and the third hard mask on the third superconducting material layer to obtain a second target superconducting device on the substrate.
9. The method according to clause 1, wherein the first hard mask is silicon nitride and the second hard mask is silicon nitride.
10. The method according to clause 2, wherein
the first hard mask of the first other region range in the first hard mask is etched away in a manner combining photolithography and dry etching; and
the superconducting material of the first other region range in the first superconducting material is etched away in a wet etching manner.
11. The method according to clause 3, wherein
the second hard mask of the second other region range in the second hard mask is etched away in a manner combining photolithography and dry etching; and
the superconducting material of the second other region range in the second superconducting material is etched away in a wet etching manner.
12. The method according to clause 7, wherein
the third hard mask of the third other region range in the third hard mask is etched away, in a manner combining photolithography and dry etching; and
the superconducting material of the third other region range in the third superconducting material is etched away in a wet etching manner.
13. The method according to any one of clauses 10 to 12, wherein an etching agent used by the wet etching manner is an SC-1 solution.
14. A method for preparing multi-superconducting material layers, comprising:
depositing a first titanium nitride layer on a substrate, the first titanium nitride layer being formed by covering first titanium nitride in a first target region range with first silicon nitride in the first target region range, wherein a thickness of the first titanium nitride in the first titanium nitride layer is a first thickness;
depositing second titanium nitride on the substrate deposited with the first titanium nitride layer;
covering the second titanium nitride with second silicon nitride; and
performing etching treatment on the second silicon nitride and the second titanium nitride to obtain a second titanium nitride layer formed by covering the second titanium nitride in a second target region range with the second silicon nitride in the second target region range, wherein a thickness of the second titanium nitride in the second titanium nitride layer is a second thickness, and the first thickness is different from the second thickness.
15. A quantum device, wherein the quantum device comprises a circuit component formed by multiple superconducting materials, and the multiple superconducting materials are obtained by using the method for preparing multi-superconducting material layers according to any one of clauses 1 to 14.
16. The quantum device according to clause 15, wherein the quantum device is a Fluxonium quantum bit.
17. A superconducting circuit, comprising the quantum device according to clause 15 or 16.
18. A quantum chip, comprising the quantum device according to clause 15 or 16.
19. A quantum computer, comprising: a quantum memory and the quantum chip according to clause 18.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A method for preparing multi-superconducting material layers, comprising:
depositing a first superconducting material layer on a substrate, the first superconducting material layer being formed by covering a first superconducting material in a first target region range with a first hard mask in the first target region range;
depositing a second superconducting material on the substrate deposited with the first superconducting material layer;
covering the second superconducting material with a second hard mask; and
performing etching treatment on the second hard mask and the second superconducting material to obtain a second superconducting material layer formed by covering the second superconducting material in a second target region range with the second hard mask in the second target region range.

2. The method according to claim 1, wherein depositing the first superconducting material layer on the substrate comprises:
depositing the first superconducting material on the substrate;
covering the first superconducting material with the first hard mask;
determining the first target region range in which the first superconducting material is to retain on the substrate; and
etching away a first hard mask of a first other region range in the first hard mask and a superconducting material of the first other region range in the first superconducting material, respectively, wherein the first other region range is a region range on the substrate in addition to the first target region range.

3. The method according to claim 1, wherein performing etching treatment on the second hard mask and the second superconducting material to obtain a second superconducting material layer formed by covering the second superconducting material in a second target region range with the second hard mask in the second target region range comprises:
etching away a second hard mask of a second other region range in the second hard mask and a superconducting material of the second other region range in the second superconducting material, respectively, wherein the second other region range is a region range on the substrate in addition to the second target region range.

4. The method according to claim 1, wherein after performing etching treatment on the second hard mask and the second superconducting material to obtain a second superconducting material layer formed by covering the second superconducting material in a second target region range with the second hard mask in the second target region range, the method further comprises:
etching away the first hard mask on the first superconducting material layer and the second hard mask on the second superconducting material layer to obtain a first target superconducting device on the substrate.

5. The method according to claim 4, wherein etching away the first hard mask on the first superconducting material layer and the second hard mask on the second superconducting material layer to obtain a first target superconducting device on the substrate comprises:
etching away the first hard mask on the first superconducting material layer and the second hard mask on the second superconducting material layer by using a dilute hydrofluoric acid (DHF) solution to obtain the first target superconducting device on the substrate.

6. The method according to claim 1, wherein after performing etching treatment on the second hard mask and the second superconducting material to obtain a second superconducting material layer formed by covering the second superconducting material in a second target region range with the second hard mask in the second target region range, the method further comprises:
depositing a third superconducting material on the first superconducting material layer and a first other region range, wherein the first other region range is a region range on the substrate in addition to the first target region range;
covering the third superconducting material with a nitride used as a third hard mask;
determining a third target region range in which the third superconducting material is to retain on the substrate; and
performing etching treatment on the third hard mask and the third superconducting material to obtain a third superconducting material layer formed by covering the third superconducting material in the third target region range with the third hard mask in the third target region range.

7. The method according to claim 6, wherein performing etching treatment on the third hard mask and the third superconducting material to obtain a third superconducting material layer formed by covering the third superconducting material in the third target region range with the third hard mask in the third target region range comprises:
etching away a third hard mask of a third other region range in the third hard mask, and a superconducting material of the third other region range in the third superconducting material, respectively, wherein the third other region range is a region range on the substrate in addition to the third target region range.

8. The method according to claim 6, wherein after performing etching treatment on the third hard mask and the third superconducting material to obtain a third superconducting material layer formed by covering the third superconducting material in the third target region range with the third hard mask in the third target region range, the method further comprises:
etching away the first hard mask on the first superconducting material layer, the second hard mask on the second superconducting material layer, and the third hard mask on the third superconducting material layer to obtain a second target superconducting device on the substrate.

9. The method according to claim 1, wherein the first hard mask is silicon nitride and the second hard mask is silicon nitride.

10. The method according to claim 9, wherein the first superconducting material layer is a titanium nitride layer and the second superconducting material is a titanium nitride layer, a thickness of the first superconducting material layer is different from a thickness of the second superconducting material layer.

11. The method according to claim 2, wherein
the first hard mask of the first other region range in the first hard mask is etched away in a manner combining photolithography and dry etching; and
the superconducting material of the first other region range in the first superconducting material is etched away in a wet etching manner.

12. The method according to claim 3, wherein
the second hard mask of the second other region range in the second hard mask is etched away in a manner combining photolithography and dry etching; and
the superconducting material of the second other region range in the second superconducting material is etched away in a wet etching manner.

13. The method according to claim 7, wherein
the third hard mask of the third other region range in the third hard mask is etched away, in a manner combining photolithography and dry etching; and
the superconducting material of the third other region range in the third superconducting material is etched away in a wet etching manner.

14. The method according to claim 11, wherein an etching agent used by the wet etching manner is an SC-1 solution.

15. A quantum device comprising a circuit component formed by multiple superconducting materials, and the multiple superconducting materials are obtained by using a method for preparing multi-superconducting material layers, the method comprising:
depositing a first superconducting material layer on a substrate, the first superconducting material layer being formed by covering a first superconducting material in a first target region range with a first hard mask in the first target region range;
depositing a second superconducting material on the substrate deposited with the first superconducting material layer;
covering the second superconducting material with a second hard mask; and
performing etching treatment on the second hard mask and the second superconducting material to obtain a second superconducting material layer formed by covering the second superconducting material in a second target region range with the second hard mask in the second target region range.

16. The quantum device according to claim 15, wherein the quantum device is a Fluxonium quantum bit.

17. The quantum device according to claim 15, wherein the first hard mask is silicon nitride and the second hard mask is silicon nitride.

18. The quantum device according to claim 17, wherein the first superconducting material layer is a titanium nitride layer and the second superconducting material is a titanium nitride layer, a thickness of the first superconducting material layer is different from a thickness of the second superconducting material layer.

19. A quantum chip, comprising a quantum device, wherein the quantum device comprises a circuit component formed by multiple superconducting materials, and the multiple superconducting materials are obtained by using a method for preparing multi-superconducting material layers, the method comprising:
depositing a first superconducting material layer on a substrate, the first superconducting material layer being formed by covering a first superconducting material in a first target region range with a first hard mask in the first target region range;
depositing a second superconducting material on the substrate deposited with the first superconducting material layer;
covering the second superconducting material with a second hard mask; and
performing etching treatment on the second hard mask and the second superconducting material to obtain a second superconducting material layer formed by covering the second superconducting material in a second target region range with the second hard mask in the second target region range.

20. The quantum chip according to claim 19, wherein the quantum device is a Fluxonium quantum bit.
